(19) United States
(12) Patent Application Publication
(10) Pub. No.: US 2025/0116901 A1
(43) Pub. Date: Apr. 10, 2025

(54) DISPLAY SUBSTRATE AND DISPLAY DEVICE

(71) Applicants: CHONGQING BOE OPTOELECTRONICS TECHNOLOGY CO., LTD., Chongqing (CN); BOE TECHNOLOGY GROUP CO., LTD., Beijing (CN)

(72) Inventors: Jiandong Guo, Beijing (CN); Peng Li, Beijing (CN); Zhongshan Wu, Beijing (CN); Yanlin Han, Beijing (CN); Junming Chen, Beijing (CN); Bin Wan, Beijing (CN); Guodong Yang, Beijing (CN); Xiaofeng Yin, Beijing (CN); Zhicheng Yin, Beijing (CN)

(21) Appl. No.: 18/293,735

(22) PCT Filed: Dec. 8, 2022
(86) PCT No.: PCT/CN2022/137580

§ 371 Date: Jan. 30, 2024

(51) Int. Cl. G02F 1/1343; G02F 1/1333; G02F 1/1362; G02F 1/1368; H10D 86/40

(52) U.S. Cl. CPC G02F 1/134372; G02F 1/13338; G02F 1/134336; G02F 1/134345; G02F 1/136218; G02F 1/136286; G02F 1/1368; H10D 86/441

(57) ABSTRACT

A display substrate includes a base substrate, pixel units, and data lines. At least one sub-pixel includes a common electrode, which includes a dark region electrode portion and a light transmitting region electrode portion. The common electrode is provided with slits, an end portion of at least one slit has first to third portions, and the second portion is between the first portion and the third portion. In the first direction, the first portion is arranged side by side with an adjacent dark region electrode portion in the first direction, the second portion is arranged side by side with a part of an adjacent light transmitting region electrode portion, and the third portion is arranged side by side with another part of the adjacent light transmitting region electrode portion in the first direction. An inclination of the second portion is greater than that of the third portion and less than that of the first portion.

### CROSS-REFERENCE TO RELATED APPLICATION

This application is a Section 371 National Stage Application of International Application No. PCT/CN2022/137580, filed Dec. 8, 2022, which is incorporated herein by reference in its entirety.

### TECHNICAL FIELD

The present disclosure relates to a field of display technology, in particular to a display substrate and a display device.

### BACKGROUND

With a development of touch technology, an increasing number of display devices adopt touch control for human-computer interaction. A touch display device may be operated with fingers, and may also be operated with a stylus pen, which includes an active pen and a passive pen.

Taking the active pen as an example, during operation, an active pen signal emitted by the active pen may be transmitted to a touch integrated circuit through a touch panel, and processed by the touch integrated circuit to obtain precise coordinates of the active pen on the touch panel.

Touch display devices may be divided into add on mode touch panel, on cell touch panel, and in cell touch panel according to composition structures. With a continuous popularity of the active pen in products such as note book (NB), tablet PC (TPC), and mobile phone, etc., the in cell touch panel has attracted widespread attention due to a high compatibility with product characteristics, an excellent touch performance, a low cost, a light weight, and other various advantageous. However, a transmittance of an existing in cell touch panel is limited by many factors and is difficult to be further improved.

### SUMMARY

In view of the above problems, the present disclosure provides a display substrate and a display device.

In a first aspect of the present disclosure, a display substrate is provided, including:
a base substrate;
a plurality of pixel units provided on the base substrate, where the plurality of pixel units are arranged in an array in a first direction and a second direction; and
a plurality of data lines provided on the base substrate, where the plurality of data lines are arranged in the first direction,
where
at least one of the plurality of pixel units includes a plurality of sub-pixels, and at least one of the plurality of sub-pixels includes a common electrode;
in the at least one sub-pixel, the common electrode includes a dark region electrode portion and a light transmitting region electrode portion arranged in the second direction;
the common electrode are provided with a plurality of slits, at least one of the plurality of slits includes at least one end portion, the at least one end portion has a first portion, a second portion and a third portion arranged in the second direction, the second portion is located between the first portion and the third portion, the first portion is arranged side by side with an adjacent dark region electrode portion in the first direction, the second portion is arranged side by side with a part of an adjacent light transmitting region electrode portion in the first direction, and the third portion is arranged side by side with another part of the adjacent light transmitting region electrode portion in the first direction; and
an orthographic projection of the at least one end portion of the at least one slit on the base substrate is inclined with respect to the second direction, and an inclination of the second portion of the end portion is greater than an inclination of the third portion of the end portion and less than an inclination of the first portion of the end portion.

According to embodiments of the present disclosure, the at least one sub-pixel further includes a thin film transistor, and in the at least one sub-pixel, the dark region electrode portion of the common electrode includes a first dark region electrode portion, and the at least one end portion of the at least one slit includes a first end portion, where
an orthographic projection of the first dark region electrode portion on the base substrate is on a side of an orthographic projection of the light transmitting region electrode portion on the base substrate away from an orthographic projection of the thin film transistor configured to drive the at least one sub-pixel on the base substrate; and
the first end portion and an adjacent first dark region electrode portion are arranged side by side in the first direction.

According to embodiments of the present disclosure, in the at least one sub-pixel, the dark region electrode portion of the common electrode further includes a second dark region electrode portion, and in the second direction, an orthographic projection of the second dark region electrode portion on the base substrate is on a side of the orthographic projection of the light transmitting region electrode portion on the base substrate close to the orthographic projection of the thin film transistor configured to drive the at least one sub-pixel on the base substrate; and
the at least one end portion of the at least one slit further includes a second end portion, and the first portion of the second end portion is arranged side by side with an adjacent second dark region electrode portion in the first direction.

According to embodiments of the present disclosure, the at least one sub-pixel further includes a thin film transistor, and in the at least one sub-pixel, the dark region electrode portion of the common electrode includes a second dark region electrode portion, and the at least one end portion of the at least one slit includes a second end portion, where
an orthographic projection of the second dark region electrode portion on the base substrate is on a side of an orthographic projection of the light transmitting region electrode portion on the base substrate close to an orthographic projection of the thin film transistor configured to drive the at least one sub-pixel on the base substrate; and
the second end portion and an adjacent second dark region electrode portion are arranged side by side in the first direction.

According to embodiments of the present disclosure, in the at least one sub-pixel, the plurality of slits on the common electrode include second end portions close to the thin film transistor, and the plurality of slits include a first slit and a second slit; and
in the second direction, an orthographic projection of the second end portion of the first slit on the base substrate protrudes from an orthographic projection of the second end portion of the second slit on the base substrate.

According to embodiments of the present disclosure, in the at least one sub-pixel, an orthographic projection of the second portion of the second end portion of the first slit on the base substrate at least partially protrudes from an orthographic projection of the first portion of the second end portion of the second slit on the base substrate in the second direction.

According to embodiments of the present disclosure, in the at least one sub-pixel, an orthographic projection of the second portion of the second end portion of the first slit on the base substrate at least partially overlaps with the orthographic projection of the thin film transistor configured to drive the at least one sub-pixel on the base substrate in the first direction.

According to embodiments of the present disclosure, the at least one slit includes a first end portion and a second end portion, and an extension direction of the third portion of the first end portion intersects with or is parallel to an extension direction of the third portion of the second end portion.

According to embodiments of the present disclosure, in the at least one end portion of the at least one slit, an orthographic projection of the first portion on the base substrate is inclined with respect to the second direction at a first inclined angle, an orthographic projection of the second portion on the base substrate is inclined with respect to the second direction at a second inclined angle, where the first inclined angle and the second inclined angle are acute angles, and a ratio of the second inclined angle to the first inclined angle ranges from 0.1:1 to 0.3:1.

According to embodiments of the present disclosure, in the at least one end portion of the at least one slit, an orthographic projection of the third portion on the base substrate is inclined with respect to the second direction at a third inclined angle, the third inclined angle is an acute angle, and a ratio of the third inclined angle to the second inclined angle ranges from 0.5:1 to 0.9:1.

According to embodiments of the present disclosure, in the at least one end portion of the at least one slit, a ratio of a size of the second portion in the second direction to a size of the first portion in the second direction ranges from 2.7:1 to 3.3:1.

According to embodiments of the present disclosure, the display substrate further includes a plurality of touch lines provided on the base substrate, where the at least one sub-pixel further includes a pixel electrode, and the plurality of touch lines are arranged in the first direction; and
the plurality of slits of the common electrode of the at least one sub-pixel further include a third slit, and for the pixel electrode of the at least one sub-pixel and a touch line closest to the pixel electrode in the first direction, an orthographic projection of the pixel electrode on the base substrate and an orthographic projection of the touch line on the base substrate at least partially overlap with an orthographic projection of the third slit in the at least one sub-pixel on the base substrate, and the orthographic projection of the pixel electrode on the base substrate is spaced apart from the orthographic projection of the touch line on the base substrate.

According to embodiments of the present disclosure, in the at least one sub-pixel, in the first direction, the orthographic projection of the third slit on the base substrate is on a side of an orthographic projection of the first slit on the base substrate away from an orthographic projection of the second slit on the base substrate.

According to embodiments of the present disclosure, the display substrate further includes a plurality of shielding electrodes in a common electrode layer, and an orthographic project of at least one of the plurality of shielding electrodes on the base substrate covers an orthographic projection of at least one of the plurality of data lines on the base substrate.

According to embodiments of the present disclosure, the plurality of touch lines and the plurality of data lines are arranged in a same layer and made of a same material, and the touch line is loaded with a same electrical signal as the common electrode in a common electrode layer.

According to embodiments of the present disclosure, in the at least one sub-pixel, an orthographic projection of the second end portion of the third slit on the base substrate protrudes from the orthographic projection of the second end portion of the second slit on the base substrate in the second direction.

According to embodiments of the present disclosure, in the at least one sub-pixel, the orthographic projection of the second end portion of the first slit on the base substrate protrudes from an orthographic projection of the second end portion of the third slit on the base substrate in the second direction.

According to embodiments of the present disclosure, in the at least one sub-pixel, a ratio of a slid width of the third slit to a slit width of the first slit ranges from 2:1 to 3:1.

According to embodiments of the present disclosure, in the at least one sub-pixel, an orthographic projection of the first portion of the second end portion of the third slit at least partially overlaps with the orthographic projection of the thin film transistor configured to drive the at least one sub-pixel on the base substrate in the first direction.

According to embodiments of the present disclosure, at least one of the plurality of touch lines includes a touch line body and a transfer portion arranged in the second direction, a portion connecting the touch line body and the transfer portion is provided with a bending structure, and an orthographic projection of the second end portion of the third slit in the at least one sub-pixel on the base substrate at least partially overlaps with an orthographic projection of the bending structure on the base substrate.

According to embodiments of the present disclosure, the at least one sub-pixel includes a light transmitting region and a dark region at least partially surrounding the light transmitting region, and a transmittance of the dark region is less than a transmittance of the light transmitting region; and
in the at least one sub-pixel, an orthographic projection of the dark region electrode portion of the common electrode on the base substrate is located within a range of an orthographic projection of the dark region on the base substrate, and an orthographic projection of the light transmitting region electrode portion on the base substrate is located within a range of an orthographic projection of the light transmitting region on the base substrate.

According to embodiments of the present disclosure, a size of the dark region electrode portion in the second direction ranges from 2 μm to 3 μm.

In a second aspect of the present disclosure, a display device is provided, including the display substrate as described above.

### BRIEF DESCRIPTION OF THE DRAWINGS

The above contents and other objectives, features and advantages of the present disclosure will be more apparent through the following descriptions of embodiments of the present disclosure with reference to the accompanying drawings, in which:

FIG. 1A schematically shows a schematic diagram of an in cell touch panel using 1P1T configuration in an example;

FIG. 1B schematically shows a schematic diagram of an in cell touch panel using 1P3T configuration in an example;

FIG. 2 schematically shows a schematic diagram of a display substrate in an embodiment of the present disclosure;

FIG. 3 schematically shows a diagram of some film layers of the display substrate that are stacked in an embodiment of the present disclosure;

FIG. 4 schematically shows a schematic diagram of two sub-pixels arranged in a first direction in an embodiment of the present disclosure;

FIG. 5 shows an enlarged view at position M in FIG. 4;

FIG. 6 schematically shows a schematic diagram of a light emitting region of a sub-pixel in an embodiment of the present disclosure;

FIG. 7 schematically shows a schematic diagram of inclined angles of various portions

of a first end portion in an embodiment of the present disclosure;

FIG. 8 schematically shows a schematic diagram of division of slits of a common electrode based on their inclinations;

FIG. 9 shows an enlarged view at position N in FIG. 4;

FIG. 10 schematically shows a schematic diagram of sizes of various slits in an embodiment of the present disclosure;

FIG. 11 schematically shows a schematic diagram of an electric field formed for driving liquid crystals to deflect in a comparative example;

FIG. 12 schematically shows a schematic diagram of an electric field formed for driving liquid crystals to deflect in an embodiment of the present disclosure; and

FIG. 13 schematically shows a comparison diagram between a light emitting area of a sub-pixel in a comparative example and a light emitting area of a sub-pixel in an embodiment of the present disclosure.

### DETAILED DESCRIPTION OF EMBODIMENTS

In order to make objectives, technical solutions and advantages of embodiments of the present disclosure clearer, technical solutions of embodiments of the present disclosure will be clearly and completely described below with reference to the accompanying drawings. Obviously, the described embodiments are just some embodiments rather than all embodiments of the present disclosure. Based on the described embodiments of the present disclosure, all additional embodiments obtained by those ordinary skilled in the art without carrying out inventive effort fall within the scope of protection of the present disclosure.

It will be noted that in the accompanying drawings, for clarity and/or description purposes, a size and relative size of an element may be enlarged. Accordingly, the size and relative size of each element need not to be limited to those shown in the FIG.s. In the specification and the accompanying drawings, the same or similar reference numerals represent the same or similar components.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe a relationship between elements, such as “between” and “directly between”, “adjacent to” and “directly adjacent to”, “on” and “directly on”, and so on, will be interpreted in a similar manner. Moreover, the term “connection” may refer to a physical connection, an electrical connection, a communicative connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For objectives of the present disclosure, “at least one selected from X, Y or Z” and “at least one selected from a group consisting of X, Y and Z” may be interpreted as only X, only Y, only Z, or any combination of two or more of X, Y and Z, such as XYZ, XYY, YZ and ZZ. As used herein, the term “and/or” includes any and all combinations of one or more of the listed related items.

It will be noted that although the terms “first”, “second”, and so on may be used herein to describe various components, members, elements, regions, layers and/or portions, these components, members, elements, regions, layers and/or portions will not be limited by these terms. Rather, these terms are used to distinguish one component, member, element, region, layer and/or portion from another one. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, may be used herein to describe a relationship between an element or feature and another element or feature as shown in the FIG.s. It will be understood that the spatial relationship terms are intended to cover other different orientations of a device in use or operation in addition to the orientation described in the FIG.s. For example, if a device in the FIG.s is turned upside down, an element or feature described as “below” or “under” another element or feature will be oriented “above” or “on” the another element or feature.

Here, the terms “substantially”, “about”, “approximately” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the terms “substantially”, “about” or “approximately” used herein includes a stated value and means that a specific value determined by those ordinary skilled in the art is within an acceptable range of deviation. For example, “about” may mean being within one or more standard deviations, or within ±30%, ±20%, ±10% or ±5% of the stated value.

It will be noted that the expression “the same layer” herein refers to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art will understand that, unless otherwise specified, the expression “height” or “thickness” herein refers to a size in a direction perpendicular to a surface of each film layer provided on the display substrate, that is, a size in a light exit direction of the display substrate, or called a size in a normal direction of the display device.

At present, a cell touch display panel may adopts a pixel design such as 1P1T, 1P2T or 1P3T, where 1P1T refers to one pixel unit corresponding to one touch line, 1P2T refers to one pixel unit corresponding to two touch lines, and 1P3T refers to one pixel unit corresponding to three touch lines.

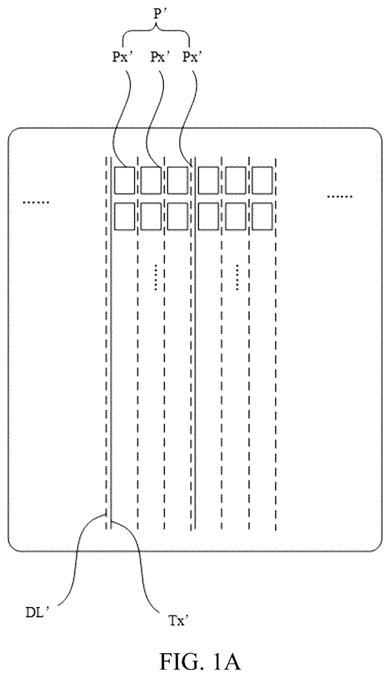

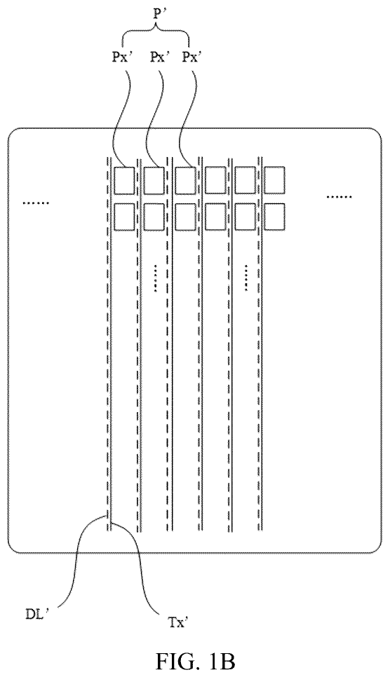

For example, FIG. 1A schematically shows a schematic diagram of an in cell touch panel using 1P1T configuration in an example, and FIG. 1B schematically shows a schematic diagram of an in cell touch panel using 1P3T configuration in an example. Referring to FIG. 1A, in an in cell touch panel using 1PIT, one pixel unit P′ corresponds to one touch line Tx′. For example, the pixel unit P′ includes a plurality of sub-pixels Px′ with different colors, and the touch line Tx′ is located on a left side of a leftmost sub-pixel Px′ in the pixel unit P′ corresponding to the touch line Tx′. Referring to FIG. 1B, in an in cell touch panel using 1P3T, one pixel unit P′ corresponds to three touch lines Tx′. For example, the three touch lines Tx′ are respectively located on the left side of each sub-pixel Px′ in the pixel unit P′ corresponding to the three touch lines Tx′.

For example, an in cell touch panel in a mobile phone may adopt the pixel design of 1P1T. Compared with a mobile phone, a display panel in a notebook has a larger size, and more touch lines need to be provided so as to ensure the touch effect. Therefore, the display panel in the notebook may adopt the pixel design of 1P3T.

Continuing to refer to FIG. 1A and FIG. 1B, in the examples shown in these two figures, touch lines Tx′ and data lines DL′ are arranged in a same layer and made of a same material in order to save costs, and a touch line Tx′ is substantially parallel to an adjacent data line DL′. Such approach may reduce costs but also has some defects. Specifically, since the touch line Tx′ and the adjacent data line DL′ are arranged in the same layer and parallel to each other, the touch line Tx′ may occupy a light emitting area of the sub-pixel Px′, so that the light emitting efficiency of the product may be affected. Moreover, as the number of touch lines Tx′ increases, an influence of that problem may significantly increases. For example, the number of touch lines Tx′ in a display panel using 1P3T is about three times the number of touch lines Tx′ in a display panel using 1PIT, then the case that the touch line Tx′ occupies the light emitting area of the sub-pixel Px′ may be intensified in the display panel using 1P3T, which may result in a low transmittance of the in cell touch panel using 1P3T. Therefore, how to improve the transmittance of such product has become an imperative technical problem to be solved.

In view of this, embodiments of the present disclosure provide a display substrate, which includes a base substrate, a plurality of pixel units provided on the base substrate, a plurality of data lines provided on the base substrate, a common electrode layer provided on the base substrate, and a thin film transistor layer provided on the base substrate. The plurality of pixel units are arranged in an array in a first direction and a second direction. The plurality of data lines are arranged in the first direction. At least one pixel unit includes a plurality of sub-pixels, and at least one sub-pixel includes a common electrode in the common electrode layer and a thin film transistor in the thin film transistor layer. In the at least one sub-pixel, the common electrode includes a dark region electrode portion and a light transmitting region electrode portion that are arranged in the second direction. The common electrode is provided with a plurality of slits, and at least one slit includes at least one end portion. The at least one end portion has a first portion, a second portion, and a third portion that are arranged in the second direction, where the second portion is between the first portion and the third portion. The first portion is arranged side by side with an adjacent dark region electrode portion in the first direction, the second portion is arranged side by side with a part of an adjacent light transmitting region electrode portion in the first direction, and the third portion is arranged side by side with another part of the adjacent light transmitting region electrode portion in the first direction. An orthographic projection of the at least one end portion of the at least one slit on the base substrate is inclined with respect to the second direction, and the second portion of the end portion is more inclined with respect to the second direction than the third portion and is less inclined with respect to the second direction than the first portion.

In embodiments of the present disclosure, the first portion of the slit may also be referred to as a corner structure, and Trace Mura may be reduced through the first portion. The inclination of the first portion is large, and a size of the first portion in the second direction may be positively related to an area of the dark region. Based on this, in the embodiments of the present disclosure, the second portion, the inclination of which is between that of the first portion and that of the third portion, is added between the first portion and the third portion of the slit, so that the second portion and the first portion may jointly reduce the Trace Mura and the size of the first portion in the second direction is reduced. In this way, the area of the dark region may be reduced, and thus the transmittance may be improved.

The display substrate according to the embodiments of the present disclosure will be described in detail below.

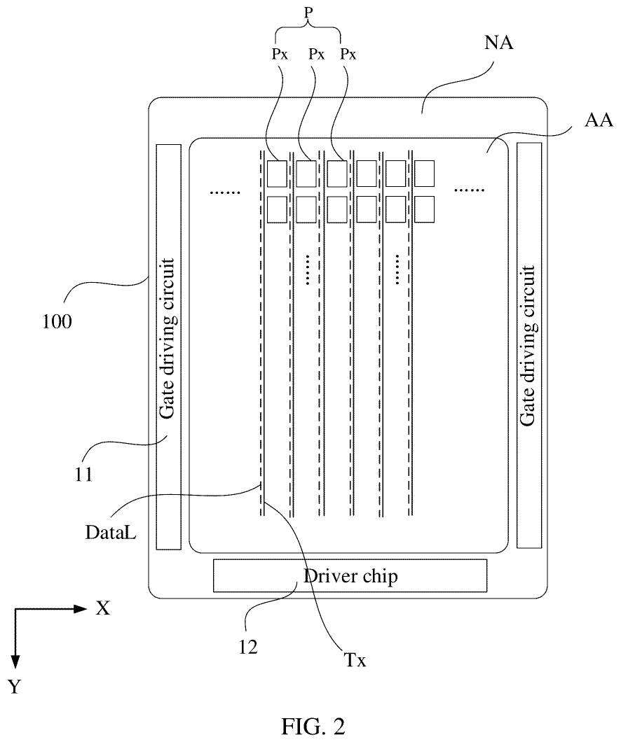

FIG. 2 schematically shows a schematic diagram of a display substrate in an embodiment of the present disclosure. Referring to FIG. 2, the display substrate in such embodiments includes a display area AA and a peripheral area NA at least partially surrounding the display area AA.

The display substrate may further include a gate driving circuit 11 and a driver chip 12 in the peripheral area NA. For example, the gate driving circuit 11 may be provided on at least one side of the display area AA. In embodiments shown in FIG. 2, gate driving circuits 11 are provided on a left side and a right side of the display area AA, respectively. It will be noted that the left side and the right side may refer to a left side and a right side of the display substrate (screen) viewed by human eyes during display. For example, the driver chip 12 may be located on at least one side of the display area AA. In embodiments shown in FIG. 2, the driver chip 12 is provided on a lower side of the display area AA. It will be noted that the lower side may be a lower side of the display substrate (screen) viewed by human eyes during display.

The gate driving circuit 11 may be implemented by a shift register, and the gate driving circuit 11 may provide scanning signals to gate lines (not shown) in the display substrate. The driver chip 12 may include a data driving circuit, which may provide data signals to data lines DL in the display substrate.

It will be noted that FIG. 2 shows the gate driving circuit 11 is on the left side and the right side of the display area AA, and the driver chip 12 is on the lower side of the display area AA, but the embodiments of the present disclosure are not limited to this. The gate driving circuit 11 and the driver chip 12 may be provided at any suitable position in the peripheral area NA.

For example, GOA, namely Gate Driver on Array, may be applied to the gate driving circuit 11. According to GOA, the gate driving circuit 11 is provided directly on the array substrate to replace an external chip. Each GOA unit serves as a stage of shift register, and each stage of shift register is connected to a gate line. Scanning signals are sequentially output through stages of shift registers to achieve progressive scanning of pixel units. In some embodiments, each stage of shift register may also be connected to more than one gate line, which may adapt to a development trend of high resolution and narrow bezel of display substrates.

The display substrate may further include a base substrate 100 and a plurality of pixel units P provided on the base substrate 100 and in the display area AA. The plurality of pixel units P are arranged in an array in a first direction X and a second direction Y intersecting with the first direction X. For example, the first direction X is a horizontal direction in FIG. 2, and the second direction Y is a vertical direction in FIG. 2, that is, the first direction X and the second direction Y are perpendicular to each other.

At least one pixel unit P includes a plurality of sub-pixels Px, which may display different colors through corresponding color filters. For example, a plurality of sub-pixels Px in a pixel unit P may include a first sub-pixel, a second sub-pixel, and a third sub-pixel. The first sub-pixel may be matched with a red color filter to emit red light, the second sub-pixel may be matched with a green color filter to emit green light, and the third sub-pixel may be matched with a blue color filter to emit blue light.

It will be noted that in FIG. 2, a shape of an orthographic projection of the sub-pixel on the base substrate is schematically shown as a rectangle, but the embodiments of the present disclosure are not limited to this. In addition, an arrangement of the three sub-pixels in the pixel unit P is not limited to that shown in FIG. 2.

The display substrate may further include a plurality of data lines DL provided on the base substrate 100 and in the display area AA. As shown in FIG. 2, at least one of the plurality of data lines DL may extend from an upper end of the display area AA to a lower end of the display area AA, so as to be electrically connected to the driver chip 12 located at the lower end of the display area AA.

In the embodiments of the present disclosure, the plurality of data lines DL are arranged in the first direction X, and at least one data line DL is electrically connected to more than one sub-pixel Px arranged in the second direction.

Referring to FIG. 2, the plurality of sub-pixels Px on the display substrate may be arranged in an array in the first direction X and the second direction Y, and at least part of each column of sub-pixels Px may be electrically connected to a same data line DL. For example, for a column of sub-pixels Px, all sub-pixels Px in the column of sub-pixels Px are electrically connected to a same data line DL; or odd-numbered rows of sub-pixels Px in that column of sub-pixels Px are electrically connected to a data line, while even-number rows of sub-pixels Px in that column of sub-pixels Px are electrically connected to another data line DL.

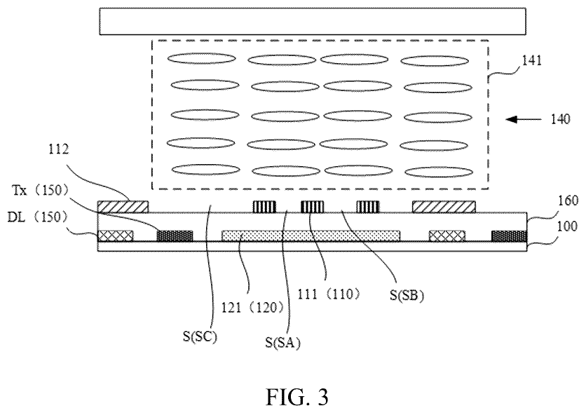

FIG. 3 schematically shows a diagram of some film layers of the display substrate that are stacked in an embodiment of the present disclosure. It will be noted that for clarity, FIG. 3 only shows the base substrate 100, a common electrode layer 110, a pixel electrode 120, a liquid crystal layer 140, a second conductive layer 150, and an insulation layer 160 between conductive film layers, and other film layers such as a gate layer is omitted. As shown in FIG. 3, the display substrate may further include the common electrode layer 110 and the pixel electrode layer 120 provided on the base substrate 100, and at least one sub-pixel Px may include a common electrode 111 located in the common electrode layer 110 and a pixel electrode 121 located in the pixel electrode layer 120. Optionally, the pixel electrode layer 120 is between the common electrode layer 110 and the base substrate 100.

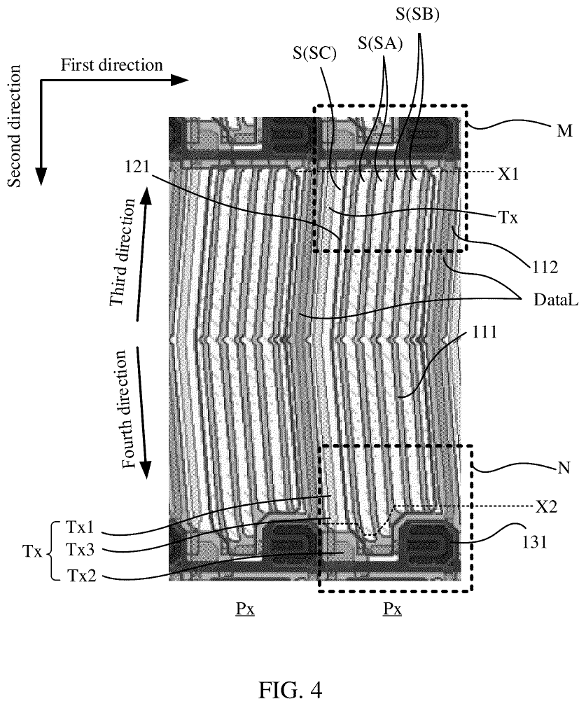

The display substrate in the present disclosure may be applied to a liquid crystal display panel. In embodiments of the present disclosure, an orthographic projection of the pixel electrode 121 of the sub-pixel Px on the base substrate 100 is inclined with respect to the second direction Y. For example, FIG. 4 schematically shows a schematic diagram of two sub-pixels arranged in the first direction in an embodiment of the present disclosure. Referring to FIG. 4, the pixel electrode 121 in the sub-pixel Px may include two parts, one part is towards a third direction, and the other part is towards a fourth direction. The third direction, the fourth direction and the second direction Y intersect with one another. An orthographic projection of the common electrode 111 in the sub-pixel Px on the base substrate 100 is inclined with respect to the second direction Y. For example, referring to FIG. 4, the common electrode 111 in the sub-pixel Px includes two parts, one part is towards the third direction, and the other part is towards the fourth direction. In this way, a dual domain electric field may be formed between the pixel electrode 121 and the common electrode 111, so that color deviation of a liquid crystal display panel may be reduced, and a viewing angle may be increased.

An orthographic projection of a signal line adjacent to the sub-pixel Px in the first direction X on the base substrate 100 may also be inclined with respect to the second direction Y. For example, referring to FIG. 4, the data line DL may also include two parts, which are respectively inclined towards the third direction and the fourth direction. It will be noted that the signal line adjacent to the sub-pixel Px may specifically mean that no other signal line of the same type is provided between the two. For example, the data line DL being adjacent to the sub-pixel Px may specifically mean that no other data line DL is provided between the sub-pixel Px and the data line DL adjacent to the sub-pixel Px.

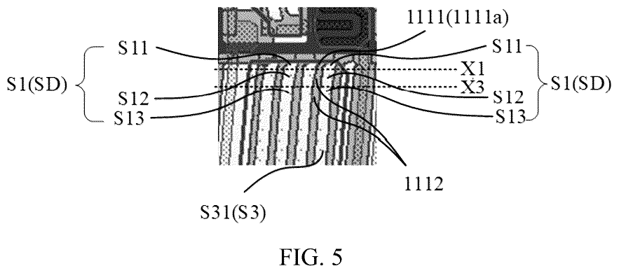

FIG. 5 shows an enlarged view at position M in FIG. 4. Referring to FIG. 4 and FIG. 5, in at least one sub-pixel Px, the common electrode 111 includes a dark region electrode portion 1111 and a light transmitting region electrode portion 1112 arranged in the second direction Y.

In the embodiments of the present disclosure, the display substrate may refer to a display substrate applied to a liquid crystal display panel. As shown in FIG. 3, the display substrate further includes a liquid crystal layer 140, and the at least one sub-pixel Px further includes a light adjustment portion 141 in the liquid crystal layer 140. During display of the liquid crystal display panel, driving voltages may be applied to the pixel electrode 121 and the common electrode 111 of the sub-pixel Px that needs to emit light, so that an electric field is formed between the common electrode 111 and the pixel electrode 121 of the sub-pixel Px. The liquid crystals in the light adjustment portion 141 of the sub-pixel Px is deflected under the drive of the electric field, so that light control may be achieved.

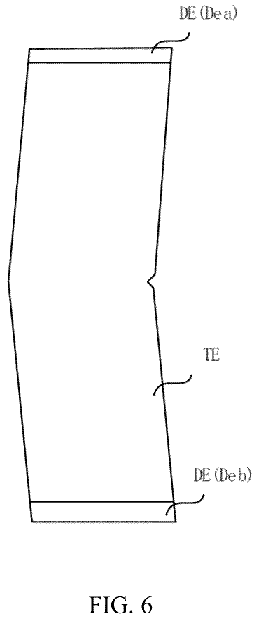

FIG. 6 schematically shows a schematic diagram of a light emitting region of a sub-pixel in an embodiment of the present disclosure. Referring to FIG. 6, for a sub-pixel Px, the sub-pixel may include a light transmitting region TE and a dark region DE at least partially surrounding the light transmitting region TE. When a driving voltage is applied to the sub-pixel Px to drive the sub-pixel Px to emit light, the light transmitting region TE is used to permit the exit of light, so as to achieve the display function. The dark region DE permits the exit of less light or even does not permit the exit of light, and thus presents a dark state visually, hence it is called the dark region DE.

It will be noted that FIG. 6 only shows relative positions of the light transmitting region TE and the dark region DE, which do not limit their specific appearance.

In some specific embodiments, an orthographic projection of the dark region electrode portion 1111 on the base substrate 100 is located within a range of an orthographic projection of the dark region DE on the base substrate 100. In the embodiments of the present disclosure, the dark region DE and the light transmitting region TE are arranged in the second direction Y. For example, in some specific embodiments, the dark region DE includes a first dark region Dea, which is closer to an upper row of sub-pixels Px than the light transmitting region TE. For another example, in some specific embodiments, the dark region DE includes a second dark region Deb, which is closer to a lower row of sub-pixels Px than the light transmitting region TE. For another example, in some specific embodiments, the dark region DE includes at least two parts arranged in the second direction Y, and the two parts are separated by the light transmitting region TE, where one part is close to the upper row of sub-pixels Px and may be called as the first dark region Dea, and the other part is close to the lower row of sub-pixels Px and may be called as the second dark region Deb.

Accordingly, the dark region electrode portion 1111 may also include one dark region electrode portion or two dark region electrode portions. For example, in some specific embodiments, the dark region electrode portion 1111 includes a first dark region electrode portion 1111a, which is located in the first dark region Dea. For another example, in some specific embodiments, the dark region electrode portion 1111 includes a second dark region electrode portion 1111b, which is located in the second dark region Deb. For yet another example, in some specific embodiments, the dark region electrode portion 1111 includes the first dark region electrode portion 1111a and the second dark region electrode portion 1111b, where the first dark region electrode portion 1111a is located in the first dark region Dea, and the second dark region electrode portion 1111b is located in the second dark region Deb. For clarity, the dark region electrode portion 1111 including both the first dark region electrode portion 1111a and the second dark region electrode portion 1111b is taken as example for description. However, it will be understood that this does not exclude that in some embodiments of the present disclosure, the dark region electrode portion 1111 only includes the first dark region electrode portion 1111a or only includes the second dark region electrode portion 1111b.

Referring to FIG. 5, the first dark region electrode portion 1111a may specifically refer to a portion of the common electrode 111 that is arranged side by side with a first portion S11 of a first end portion S1 of a slit S in the first direction X. Optionally, in the second direction Y, a size of the first dark region electrode portion 1111a may range from 2 μm to 3 μm.

Optionally, an orthographic projection of the light transmitting region electrode portion 1112 on the base substrate 100 is located within a range of an orthographic projection of the light transmitting region TE on the base substrate 100.

As shown in FIG. 4, the at least one sub-pixel further includes a thin film transistor 131. The electrical connection between the data line DL and the sub-pixel Px may specifically refer to an electrical connection between the data line DL and the pixel electrode 121 in the sub-pixel Px through the thin film transistor 131. As such, the thin film transistor 131 may control whether to transmit the data signal on the data line DL to the pixel electrode 121 of the corresponding sub-pixel Px, that is, the sub-pixel Px is driven to transmit light by using the thin film transistor 131, so as to achieve display. The thin film transistor 131 may be an N-type transistor or a P-type transistor, which may be determined according to actual needs and is not limited here.

In the second direction Y, an orthographic projection of the first dark region electrode portion 1111a on the base substrate 100 is on a side of the orthographic projection of the light transmitting region electrode portion 1112 on the base substrate 100 away from an orthographic projection of the thin film transistor 131 used to drive the at least one sub-pixel Px on the base substrate 100.

For example, referring to FIG. 4 and FIG. 5, taking a sub-pixel Px as an example, in the second direction Y, the first dark region electrode portion 1111a is a portion of the common electrode 111 on an upper side of the dashed line X1, and the light transmitting region electrode portion 1112 is a portion of the common electrode 111 between the dashed line X1 and the dashed line X2. The first dark region electrode portion 1111a is located on an upper side of the light transmitting region electrode portion 1112, and the thin film transistor 131 used to drive the sub-pixel Px is located on a lower side of the light transmitting region electrode portion 1112.

The common electrode 111 is provided with a plurality of slits S, and at least one slit S includes at least one end portion SD. For example, each slit S has two end portions SD, which are respectively a first end portion S1 close to an upper row of sub-pixels Px and a second end portion S2 close to a lower row of sub-pixels Px. In other words, for the two end portions SD of the at least one slit S, the end portion SD close to the thin film transistor 131 is the second end portion S2.

The first end portion S1 of the slit S may specifically refer to a portion of the slit S that is defined by extending a certain length from an edge of the slit S close to the upper row of sub-pixels Px towards a center of the slit S. The second end portion S2 of the slit S may specifically refer to a portion of the slit S that is defined by extending a certain length from an edge of the slit S close to the lower row of sub-pixels Px towards the center of the slit S.

It will be noted that the extending length may be determined according to actual needs, but the extending length needs to permit the defined end portion SD to be divided into at least three portions in the second direction Y.

The first end portion S1 in the embodiments of the present disclosure will be described below first.

The first end portion S1 has a first portion S11, a second portion S12, and a third portion S13 that are arranged in the second direction Y. The second portion S12 is located between the first portion S11 and the third portion S13. The first portion S11 is arranged side by side with an adjacent first dark region electrode portion 1111a in the first direction X, the second portion S12 is arranged side by side with a part of an adjacent light transmitting region electrode portion 1112 in the first direction X, and the third portion S13 is arranged side by side with another part of the adjacent light transmitting region electrode portion 1112 in the first direction X.

For example, as shown in FIG. 5, in the first end portion S1 of the slit S, the first portion S11 is a portion of the first end portion S1 on an upper side of the dashed line X1, the second portion S12 is a portion of the first end portion S1 between the dashed line X1 and the dashed line X3, and the third portion S13 is a portion of the first end portion S1 on a lower side of the dashed line X3.

For the first end portion S1 of a slit S, the first dark region electrode portion 1111a is located on the left and right sides of the first portion S11; a part of the light transmitting region electrode portion 1112 is located on the left and right sides of the second portion S12, and another part of the light transmitting region electrode portion 1112 is located on the left and right sides of the third portion S13.

Optionally, the slit S may include a body portion S3 between the first end portion S1 and the second end portion S2. The body portion S3 may include a first body portion S31 extending in the third direction and a second body portion S32 extending in the fourth direction, and the first body portion S31 may be located between the second body portion S32 and the third portion S13. An extension direction of the third portion S13 of the first end portion S1 may be the same as an extension direction of the first body portion S31, in other words, the third portion S13 of the first end portion S1 may also be regarded as an extension of the first body portion S31.

Optionally, the slit S may include a body portion S3 between the first end portion S1 and the second end portion S2, and the body portion S3 may extend in the third direction or extend in the fourth direction. The extension direction of the third portion S13 of the first end portion S1 may be the same as the extension direction of the first body portion S31, in other words, the third portion S13 of the first end portion S1 may also be regarded as an extension of the first body portion S31. Optionally, for two sub-pixels Px adjacent to each other in the second direction Y, the body portion S3 of one of the two sub-pixels Px extends in the third direction, and the body portion S3 of the other of the two sub-pixels Px extends in the fourth direction.

An orthographic projection of the first end portion S1 of the at least one slit S on the base substrate 100 is inclined with respect to the second direction Y. An inclination of the second portion S12 is greater than an inclination of the third portion S13 and less than an inclination of the first portion S11.

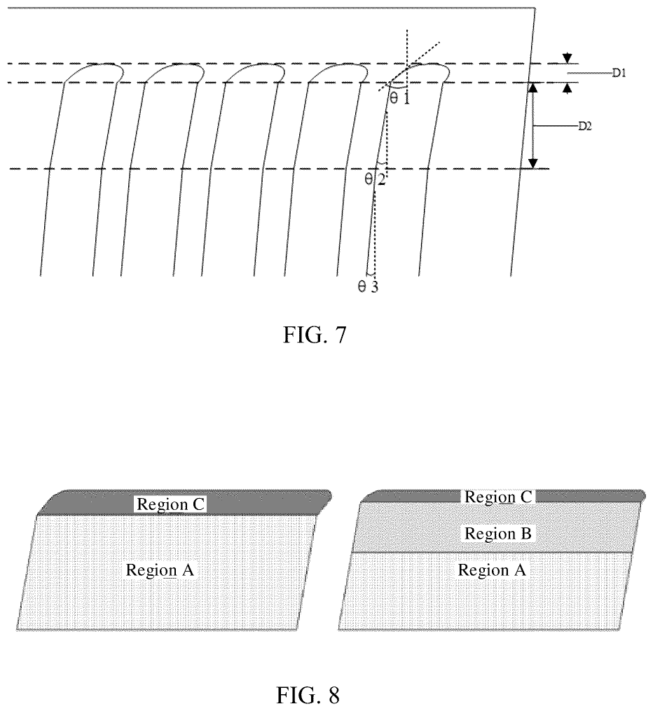

FIG. 7 schematically shows a schematic diagram of inclined angles of various portions of the first end portion in an embodiment of the present disclosure. Referring to FIG. 7, in the first end portion S1 of at least one slit S, an orthographic projection of the first portion S11 on the base substrate 100 is inclined with respect to the second direction Y at a first inclined angle θ1, an orthographic projection of the second portion S12 on the base substrate 100 is inclined with respect to the second direction Y at a second inclined angle θ2, and an orthographic projection of the third portion S13 on the base substrate 100 is inclined with respect to the second direction Y at a third inclined angle θ3. The second inclined angle θ2 is less than the first inclined angle θ1, and the second inclined angle θ2 is greater than the third inclined angle θ3.

In embodiments of the present disclosure, the first portion S11 is mainly used to reduce Trace Mura, and the larger the size of the first portion S11 in the second direction Y, the better the Trace Mura is reduced. The inclination of the first portion S11 is large, and the size of the first portion S11 in the second direction Y has an influence on an area of the first dark region Dea. Specifically, it is difficult for a pattern of the common electrode 111 defined by the first portion S11 (including the dark region electrode portion 1111 and an edge of the common electrode 111 extending in the first direction) to form a uniform electric field, and the non-uniform electric field may fail to drive the liquid crystals in the liquid crystal layer 140 to be arranged in a regular manner, resulting in a dark region during display. Moreover, the larger the size of the first portion S11 in the second direction Y, the larger the size of the corresponding dark region electrode portion 1111 in the second direction Y, which may cause a large size of the dark region in the second direction Y.

Specifically, for the first end portion S1 of the slit S, the larger the size of the first portion S11 in the second direction Y, the larger the size of the first dark region electrode portion 1111a in the second direction Y, so that the size of the first dark region Dea in the second direction Y is increased. In the embodiments of the present disclosure, the second portion S12 is added between the first portion S11 and the third portion S13 of the first end portion S1, and since the inclination of the second portion S12 is between that of the first portion S11 and that of the third portion S13, the second portion S12 may reduce the Trace Mura to some extent. The embodiments of the present disclosure utilize a combination of the second portion S12 and the first portion S11 to reduce the Trace Mura, so that the size of the first portion S11 in the second direction Y may be reduced as much as possible without aggravating the Trace Mura. Accordingly, the area of the first dark region electrode portion 1111a may be reduced, which may in turn reduce the area of the first dark region Dea, so that the area of the light transmitting region may be increased, and the transmittance of the sub-pixel Px may be improved.

For example, FIG. 8 schematically shows a schematic diagram of division of slits of a common electrode based on their inclinations. A left figure in FIG. 8 schematically shows the division of a slit of a common electrode based on its inclination in a comparative example, while a right figure in FIG. 8 schematically shows the division of a slit of a common electrode based on its inclination in an embodiment of the present disclosure. Region A is a region where the third portion S13 of the first end portion S1 is located in the common electrode 111, region B is a region where the second portion S12 of the first end portion S1 is located in the common electrode 111, and region C is a region where the first portion S11 of the first end portion S1 is located in the common electrode 111. In the left figure of FIG. 8, the slit S is not provided with the second portion S12, while in the right figure of FIG. 8, the slit S is provided with the second portion S12. Referring to the left figure of FIG. 8, in order to achieve better effect of reducing Trace Mura, the region where the first portion S11 is located in the common electrode 111 (i.e., the region C in the left figure of FIG. 8) has a size of about 4 μm to 6 μm in the second direction Y. Referring to the right figure of FIG. 8, with the second portion S12 provided, the size of the region where the first portion S11 is located in the common electrode 111 (i.e., the region C in the right figure of FIG. 8) in the second direction Y may be reduced to 2.7 μm to 3.3 μm. In this way, in the embodiments of the present disclosure, by providing the second portion S12 as a transition structure in the first end portion S1, it is possible to reduce the size of the first portion S11 in the second direction Y while achieving a good effect of reducing Trace Mura, and thus the area of the first dark region Dea may be reduced and the transmittance of the sub-pixel Px may be improved.

The second end portion S2 in the embodiments of the present disclosure will be described below. It will be noted that, unless otherwise specified, the structures described below all belong to the same sub-pixel Px.

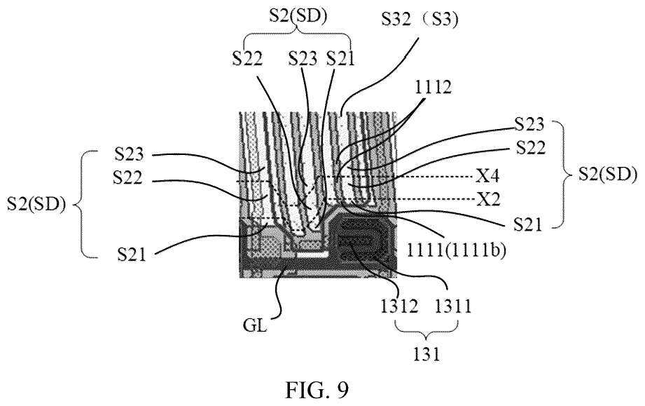

FIG. 9 shows an enlarged view at position N in FIG. 4. Referring to FIG. 4 and FIG. 9, in some specific embodiments, in the at least one sub-pixel Px, the dark region electrode portion 1111 of the common electrode 111 further includes a second dark region electrode portion 1111b.

In embodiments of the present disclosure, the portion of the dark region DE close to the lower row of sub-pixels Px is called as the second dark region Deb, and an orthographic projection of the second dark region electrode portion 1111b on the base substrate 100 at least partially overlaps with an orthographic projection of the second dark region Deb on the base substrate 100.

In the second direction Y, the orthographic projection of the second dark region electrode portion 1111b on the base substrate 100 is located on a side of the orthographic projection of the light transmitting region electrode portion 1112 on the base substrate 100 close to the orthographic projection of the thin film transistor 131 used to drive the at least one sub-pixel Px on the base substrate 100. For example, referring to FIG. 9, taking a sub-pixel Px as an example, the second dark region electrode portion 1111b is a portion of the common electrode 111 on a lower side of the dashed line X2, and the second dark region electrode portion 1111b is on a lower side of the light transmitting region electrode portion 1112.

The at least one end portion SD of the at least one slit S further includes a second end portion S2. As described above, the second end portion S2 of the slit S specifically refers to a portion of the slit S that is defined by extending a certain length from the edge of the slit S close to the lower row of sub-pixels Px to the center of the slit S. It will be noted that the extending length may be determined according to actual needs, but the extending length needs to permit the defined second end portion S2 to be divided into at least three portions in the second direction Y.

For example, the second end portion S2 has a first portion S21, a second portion S22, and a third portion S23 that are arranged in the second direction Y. The third portion S23 is arranged side by side with a part of an adjacent light transmitting region electrode portion 1112 in the first direction X, the second portion S22 is arranged side by side with another part of the adjacent light transmitting region electrode portion 1112 in the first direction X, and the first portion S21 is arranged side by side with an adjacent second dark region electrode portion 1111b in the first direction X.

For example, referring to FIG. 9, the third portion S23 is a portion of the second end portion S2 on an upper side of the dashed line X4, the second portion S22 is a portion between the dashed line X2 and the dashed line X4 of the second end portion S2, and the first portion S21 is a portion of the second end portion S2 on a lower side of the dashed line X2.

For example, referring to FIG. 9, for the second end portion S2 of a slit S, the second dark region electrode portion 1111b is located on the left and right sides of the first portion S21 of the second end portion S2; a part of the light transmitting region electrode portion 1112 is located on the left and right sides of the second portion S22 of the second end portion S2, and another part of the light transmitting region electrode portion 1112 is located on the left and right sides of the third portion S23 of the second end portion S2.

A size of the first portion S21 of the second end portion S2 in the second direction Y may be determined with reference to the first end portion S1, which will not be described in detail here.

An orthographic projection of the second end portion S2 of the at least one slit S on the base substrate 100 is inclined with respect to the second direction Y, and an inclination of the second portion S22 is greater than an inclination of the third portion S23 and less than an inclination of the first portion S21.

For example, in the second end portion S2 of the at least one slit S, an orthographic projection of the third portion S23 on the base substrate 100 is inclined with respect to the second direction Y at a fourth inclined angle, an orthographic projection of the second portion S22 on the base substrate 100 is inclined with respect to the second direction Y at a fifth inclined angle, and an orthographic projection of the first portion S21 on the base substrate 100 is inclined with respect to the second direction Y at a sixth inclined angle. The fifth inclined angle is less than the sixth inclined angle and greater than the fourth inclined angle. Optionally, the fourth inclined angle may be the same as the third inclined angle, the fifth inclined angle may be the same as the second inclined angle, and the sixth inclined angle may be the same as the first inclined angle.

In some specific embodiments, an extension direction the third portion S23 of the second end portion S2 intersects with an extension direction of the third portion S13 of the first end portion S1. Optionally, the extension direction of the third portion S23 of the second end portion S2 may be the same as the extension direction of the second body portion S32 described above. In other words, the third portion S23 of the second end portion S2 may be regarded as an extension of the second body portion S32.

The first portion S21 of the second end portion S2 is also mainly used to reduce Trace Mura. Based on a principle similar to that of providing the second portion S12 in the first end portion S1 described above, by providing the second portion S22 with an inclination between that of the third portion S23 and that of the first portion S21 in the second end portion S2, the embodiments of the present disclosure may be implemented to reduce the size of the first portion S21 of the second end portion S2 in the second direction Y without aggravating Trace Mura, so that an area of the second dark region electrode portion 1111b may be reduced accordingly, and thus the area of the second dark region Deb may be reduced, and the area of the dark region DE of the light adjustment portion may be reduced.

As such, in the embodiments of the present disclosure, by providing the second portion S12 in the first end portion S1 and providing the second portion S22 in the second end portion S2, it is possible to reduce the area of the dark region DE and thus improve the transmittance of the sub-pixel Px without aggravating Trace Mura.

Referring to FIG. 4 to FIG. 9, the plurality of slits S of the common electrode 111 may have different sizes in the second direction Y. Specifically, in at least one sub-pixel Px, the plurality of slits S of the common electrode 111 include a first slit SA and a second slit SB, and a size of the first slit SA in the second direction Y is greater than a size of the second slit SB in the second direction Y.

In a sub-pixel Px, an orthographic projection of the first end portion S1 of the first slit SA on the base substrate 100 and an orthographic projection of the first end portion S1 of the second slit SB on the base substrate 100 may be arranged side by side in the first direction X. Different from the first end portions S1, an orthographic projection of the second end portion S2 of the first slit SA on the base substrate 100 protrudes from an orthographic projection of the second end portion S2 of the second slit SB on the base substrate 100 in the second direction Y.

In embodiments of the present disclosure, the common electrode 111 is separated into a plurality of strip-shaped portions by the slits S of the common electrode 111, and the common electrode 111 forms an electric field with the pixel electrode 121 through these strip-shaped portions, where the electric field is used to drive liquid crystals to deflect. By providing the slits S in the above-mentioned manner, it is possible to maximize an area occupied by the strip-shaped portions of the common electrode 111, so as to increase the light emitting area of the sub-pixel Px.

Optionally, a width of the strip-shaped portion may range from 2 μm to 3 μm, for example, the width of the strip-shaped portion may be 2.24 μm. The width of the strip-shaped portion may refer to an average distance between two edges of the strip-shaped portion arranged in the first direction X, or the width of the strip-shaped portion may refer to a distance between two edges of the strip-shaped portion, which are arranged in the first direction X, in the first direction X.

Optionally, in a sub-pixel Px, in the first direction X, an orthographic projection of the second slit SB on the base substrate 100 is located on a side of an orthographic projection of the first slit SA on the base substrate 100 close to an orthographic projection of the data line DL electrically connected to the sub-pixel Px on the base substrate 100. Referring to FIG. 4, for the sub-pixel Px, the data line DL electrically connected to the sub-pixel Px is located on the right side of the sub-pixel Px, and the second slit SB is located on the right side the first slit SA.

In some specific embodiments, in at least one sub-pixel Px, an orthographic projection of the second portion S22 of the second end portion S2 of the first slit SA on the base substrate 100 at least partially protrudes from an orthographic projection of the first portion S21 of the second end portion S2 of the second slit SB on the base substrate 100 in the second direction Y, so that the first portion S21 of the second end portion S2 of the first slit SA is as close as possible to the lower row of sub-pixels Px. In this way, the second dark region DE of the light adjustment portion may be as close as possible to the lower row of sub-pixels, and thus the size of the light transmitting region TE of the light adjustment portion in the second direction Y may be as long as possible.

Optionally, a slit width of the first slit SA is substantially the same as a slit width of the second slit SB. In at least one sub-pixel Px, in the common electrode 111, the second portion S12 of the first end portion S1 of the first slit SA and the second portion S12 of the first end portion S1 of the second slit SB are arranged horizontally in the first direction X. The slit width may refer to an average distance between two edges of the slit S arranged in the first direction X.

In the embodiments of the present disclosure, the display substrate may further include a gate layer and a first conductive layer (not shown) provided on the base substrate 100. Referring to FIG. 9, the thin film transistor 131 includes a gate electrode located in the gate layer, and a first electrode 1311 and a second electrode 1312 located in the first conductive layer. In a thickness direction of the display substrate, a positional relationship between the gate layer and the first conductive layer may be determined according to actual needs and is not limited in the embodiments of the present disclosure. For example, when the thin film transistor 131 in the display substrate has a bottom-gate structure, the gate layer may be between the first conductive layer and the base substrate 100.

In some specific embodiments, a plurality of gate lines GL are provided on the display substrate, and at least one gate line GL is electrically connected to at least one sub-pixel Px. Optionally, at least one gate line GL is electrically connected to at least part of sub-pixels Px in a row of sub-pixels Px. For example, one gate line GL is electrically connected to all sub-pixels Px in a row of sub-pixels Px.

In embodiments of the present disclosure, the electrical connection between the gate line GL and the sub-pixel Px may be specifically an electrical connection between the gate line GL and the gate electrode of the thin film transistor 131 used to drive the sub-pixel Px.

For example, the gate electrode of the thin film transistor 131 is electrically connected to a gate line GL, and the gate driving circuit may provide a scanning signal to the gate electrode of the thin film transistor 131 through that gate line GL, so as to control turn-on and turn-off of the thin film transistor 131. The first electrode 1311 of the thin film transistor 131 is electrically connected to a data line DL, and is further electrically connected to an active layer of the thin film transistor 131. The second electrode 1312 of the thin film transistor 131 is electrically connected to the pixel electrode 121 in the sub-pixel Px, and is further electrically connected to the active layer of the thin film transistor 131. When an active-level signal is provided through the gate line GL, the thin film transistor 131 is turned on, the first electrode 1311 and the second electrode 1312 of the thin film transistor 131 are conductive through the active layer, and a data signal on the data line DL may be transmitted to the pixel electrode 121. Then, an electric field may be formed between the pixel electrode 121 and the common electrode 111 to drive the liquid crystals in the light adjustment portion 141 to deflect.

Optionally, an orthographic projection of the first electrode 1311 of the thin film transistor 131 on the base substrate 100 is substantially U-shaped, and an opening of the “U” shape is away from the data line DL electrically connected to the first electrode 1311. An orthographic projection of the second electrode 1312 of the thin film transistor 131 on the base substrate 100 is substantially I-shaped, and the second electrode 1312 of the thin film transistor 131 extends substantially in the first direction X.

In some specific embodiments, in at least one sub-pixel Px, the orthographic projection of the second portion S22 of the second end portion S2 of the first slit SA on the base substrate 100 at least partially overlaps with the orthographic projection of the thin film transistor 131 used to drive the sub-pixel Px on the base substrate 100 in the first direction X.

For example, in at least one sub-pixel Px, a first pattern is defined by the orthographic projection of the second portion S22 of the second end portion S2 of the first slit SA on the base substrate 100, a second pattern is defined by the orthographic projection of the thin film transistor 131 used to drive the sub-pixel Px on the base substrate 100, and a third pattern is defined by an orthographic projection of the gate line GL electrically connected to the sub-pixel Px on the base substrate 100. The second pattern includes a first edge and a second edge that are arranged opposite to each other in the second direction Y. The second edge overlaps at least partially with the third pattern. A distance between the first edge and the third pattern is greater than a distance between the first pattern and the third pattern.

In the embodiments of the present disclosure, the first pattern defined by the orthographic projection of the second portion S22 on the base substrate 100 may refer to a pattern defined with an outermost edge of the orthographic projection of the second portion S22 on the base substrate 100 as a boundary. The second pattern defined by the orthographic projection of the thin film transistor 131 on the base substrate 100 may refer to a pattern defined with an outermost edge of the orthographic projection of the thin film transistor 131 on the base substrate 100 as a boundary. The third pattern defined by the orthographic projection of the gate line GL on the base substrate 100 may refer to a pattern defined with an outermost edge of the orthographic projection of the gate line GL on the base substrate 100 as a boundary.

In embodiments of the present disclosure, the distance between the first edge and the third pattern may refer to a minimum distance between the first edge and the third pattern, and the distance between the first pattern and the third pattern may refer to a minimum distance between the first pattern and the third pattern.

Referring to FIG. 7, in some specific embodiments, in at least one end portion SD (such as the first end portion S1) of at least one slit S, an orthographic projection of the first portion S11 on the base substrate 100 is inclined with respect to the second direction Y at a first inclined angle θ1, and an orthographic projection of the second portion S12 on the base substrate 100 is inclined with respect to the second direction Y at a second inclined angle θ2. The first inclined angle θ1 and the second inclined angle θ2 are both acute angles. A ratio of the second inclined angle θ2 to the first inclined angle θ1 ranges from 0.1:1 to 0.3:1. For example, the ratio of the second inclined angle θ2 to the first inclined angle θ1 is 7:40. For example, the second inclined angle θ2 is set to 7°, and the first inclined angle θ1 is set to 40°.

In some specific embodiments, in at least one end portion SD (such as the first end portion S1) of at least one slit S, an orthographic projection of the third portion S13 on the base substrate 100 is inclined with respect to the second direction Y at a third inclined angle θ3, and the third inclined angle θ3 is an acute angle. A ratio of the third inclined angle θ3 to the second inclined angle θ2 ranges from 0.5:1 to 0.9:1. For example, the ratio of the third inclined angle θ3 to the second inclined angle θ2 is 5:7. For example, the third inclined angle θ3 is set to 5°, and the second inclined angle θ2 is set to 7°.

Optionally, the second inclined angle θ2 may be set between 7° and 8°, and the third inclined angle θ3 may be set between 5° and 6°.

In some specific embodiments, in at least one end portion SD (such as the first end portion S1) of at least one slit S, a ratio of a size D2 of the second portion S12 in the second direction Y to a size D1 of the first portion S11 in the second direction Y ranges from 2.7:1 to 3.3:1. For example, the ratio of the size D2 of the second portion S12 in the second direction Y to the size D1 of the first portion S11 in the second direction Y is 3:1. For example, the size D2 of the second portion S12 in the second direction Y is set to 7.5 μm, and the size D1 of the first portion S11 in the second direction Y is set to 2.5 μm.

Optionally, the size D1 of the first portion S11 in the second direction Y may be set between 2 μm and 3 μm, and the size D2 of the second portion S12 in the second direction Y may be set between 6 μm and 8 μm.

By using the display substrate in embodiments of the present disclosure, it is possible to increase the light emitting area by 1% to 2%, thereby increasing the light emitting efficiency by 1% to 2%.

In some specific embodiments, the display substrate further includes a plurality of touch lines Tx provided on the base substrate 100, and the plurality of touch lines Tx are arranged in the first direction X.

In embodiments of the present disclosure, the display substrate may adopt the 1P3T design, that is, one pixel unit corresponds to three touch lines Tx. For a specific arrangement, reference may be made to the aforementioned embodiments, and details will not be repeated here.

The plurality of touch lines Tx are arranged in the same layer and made of the same material as the plurality of data lines DL, and at least one touch line Tx is arranged parallel to a data line DL closest to the at least one touch line Tx in the first direction X. For example, referring to FIG. 3, the touch line Tx is arranged parallel to the data line DL on the left side of the touch line Tx. That is, in the case that the data line DL includes two portions extending in the third direction and the fourth direction, the touch line Tx also includes two portions, where one portion extends in the third direction, and the other portion extends in the fourth direction.

The plurality of slits S of the common electrode 111 of at least one sub-pixel Px further include a third slit SC. An orthographic projection of the third slit SC on the base substrate 100 at least partially overlaps with an orthographic projection of at least one touch line Tx on the base substrate 100, so that at least part of the touch line Tx is exposed.

In the embodiments of the present disclosure, one pixel unit P may correspond to three touch lines Tx, and each sub-pixel Px in the pixel unit P may correspond to one touch line Tx. For example, as shown in FIG. 3, a pixel unit P is traversed by three touch lines Tx, a left side of each sub-pixel Px is provided with a touch line Tx, and the touch line Tx may be exposed by the third slit SC of the sub-pixel Px on the right side of the sub-pixel Px.

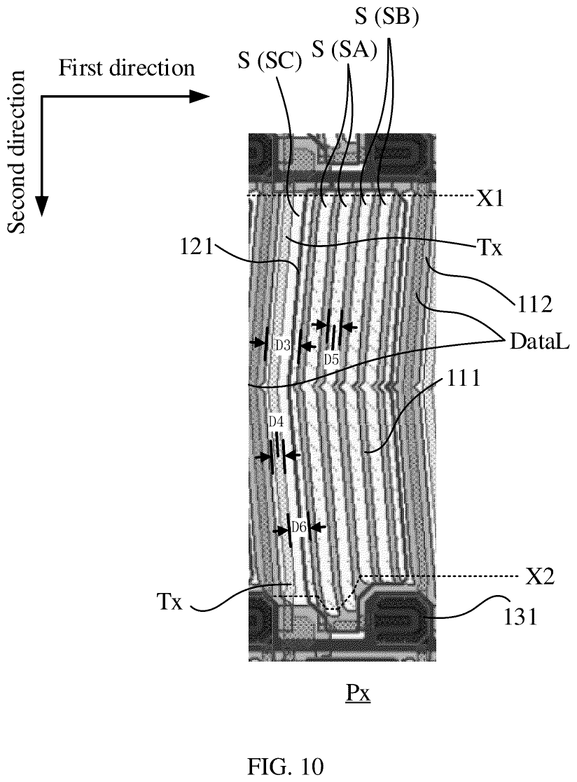

FIG. 10 schematically shows a schematic diagram of sizes of various slits in an embodiment of the present disclosure. Referring to FIG. 4 and FIG. 10, optionally, a slit width D3 of the third slit SC is greater than or equal to a line width D4 of the touch line Tx. The slit width D3 of the third slit SC may refer to an average distance between two edges of the third slit SC arranged in the first direction X. The line width D4 of the touch line Tx may refer to an average distance between two edges of the touch line Tx arranged in the first direction X.

In some specific embodiments, in at least one sub-pixel Px, a ratio of the slit width of the third slit SC to the slit width of the first slit SA ranges from 2:1 to 3:1. For example, a ratio of the slit width D3 of the third slit SC to a slit width D5 of the first slit SA is 2.5:1. The slit width D5 of the first slit SA may refer to an average distance between two edges of the first slit SA arranged in the second direction Y.

Optionally, a size of the third slit SC in the first direction X may range from 12 μm to 14 μm. The size of the third slit SC in the first direction X may specifically refer to a distance between two points arranged horizontally in the first direction X on the edges of the third slit SC.

In some specific embodiments, in at least one sub-pixel Px, a ratio of a distance D6 between an edge (such as the right edge) of the third slit SC close to the first slit SA and an edge (such as the right edge) of the touch line Tx close to the first slit SA to the slit width D5 of the first slit SA ranges from 1:1 to 2:1, where the touch line Tx is exposed by the third slit SC. For example, the ratio of the distance D6 between the edge (such as the right edge) of the third slit SC close to the first slit SA and the edge (such as the right edge) of the touch line Tx exposed by the third slit SC close to the first slit SA to the slit width D5 of the first slit SA is 1.5:1.

For example, a size between the right edge of the third slit SC and the right edge of the touch line Tx exposed by the third slit SC in the first direction X may range from 7 μm to 9 μm, where the size between the two in the first direction X may specifically refer to a distance between two points arranged horizontally in the first direction X on the two.

For example, the third slit SC includes a first side edge and a second side edge that are arranged in sequence in the second direction Y, and the touch line Tx includes a third side edge and a fourth side edge that are arranged in sequence in the second direction Y. An orthographic projection of the first side edge on the base substrate 100 is located on a side of an orthographic projection of the third side edge on the base substrate away from an orthographic projection of the fourth side edge on the base substrate 100, and the second side edge is located on a side of an orthographic projection of the fourth side edge on the base substrate 100 away from the orthographic projection of the third side edge on the base substrate 100.

For example, a left edge of the third slit SC is to the left of a left edge of the touch line Tx, and a right edge of the third slit SC is to the right of a right edge of the touch line Tx, so that the touch line Tx may be exposed to a large extent.

In the embodiments of the present disclosure, in addition to the touch line Tx, the third slit SC may also expose the pixel electrode 121 closest to the touch line Tx in the first direction X.

In some specific embodiments, the display substrate further includes the pixel electrode layer 120, and the at least one sub-pixel Px further includes a pixel electrode 121 in the pixel electrode layer 120. In at least one sub-pixel Px, for the pixel electrode 121 and the touch line Tx closest to the pixel electrode 121 in the first direction X, an orthographic projection of the pixel electrode 121 on the base substrate 100 and an orthographic projection of the touch line Tx on the base substrate 100 at least partially overlap with the orthographic projection of the third slit SC in the sub-pixel Px on the base substrate 100, and the orthographic projection of the pixel electrode 121 on the base substrate 100 is spaced apart from the orthographic projection of the touch line Tx on the base substrate 100.

For example, for a sub-pixel Px, the pixel electrode 121 includes a fifth side edge and a sixth side edge that are arranged in sequence in the second direction Y, and an orthographic projection of the fifth side edge on the base substrate 100 is located on a side of the orthographic projection of the second side edge on the base substrate 100 close to the orthographic projection of the first side edge on the base substrate 100.

For example, the right side edge of the third slit SC is to the right of the left side edge of the pixel electrode 121.

In some specific embodiments, the touch line Tx is loaded with the same electrical signal as the common electrode 111 in the common electrode layer 110, so that the touch line Tx exposed by the third slit SC and the pixel electrode 121 may form an electric field, which is used to drive liquid crystals to deflect, at an edge of the sub-pixel Px to which the pixel electrode 121 belongs. Compared to conventional solutions, such electric field may increase the size of the light transmitting region TE of the light adjustment portion in the first direction X, so that the light emitting area of the sub-pixel Px may be improved.

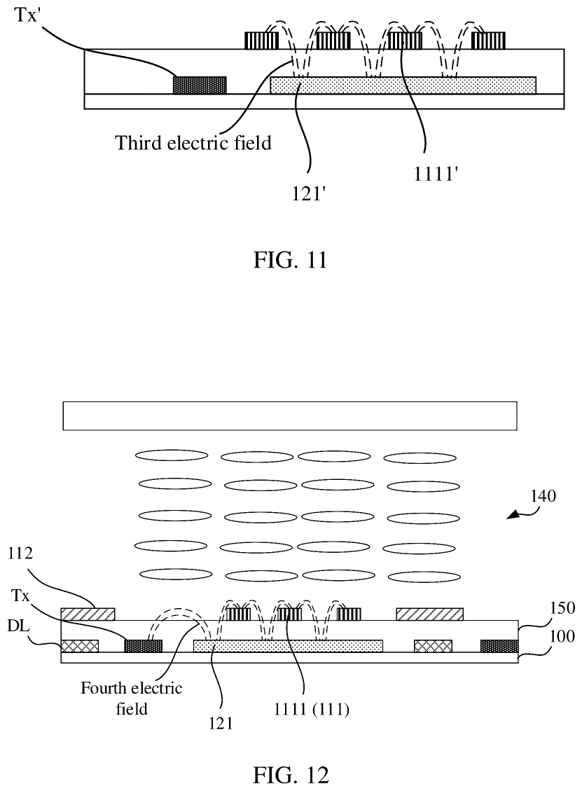

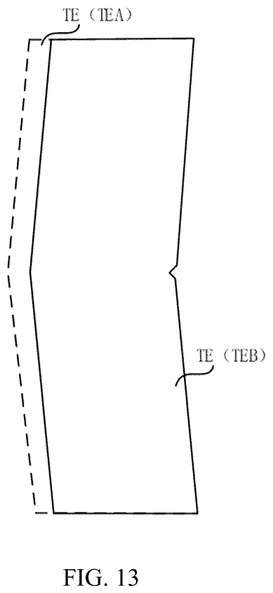

For example, FIG. 11 schematically shows a schematic diagram of an electric field formed for driving liquid crystals to deflect in a comparative example, and FIG. 12 schematically shows a schematic diagram of an electric field formed for driving liquid crystals to deflect in an embodiment of the present disclosure. The electric field formed by the pixel electrode 112′ and the common electrode 1111′ to drive liquid crystals to deflect in the comparative example is shown in FIG. 11. As the common electrode 1111′ is provided between the touch line Tx′ and the pixel electrode 112′, no electric field is formed between the touch line Tx′ and the pixel electrode 112′. Referring to FIG. 11 and FIG. 12, in the comparative example, the common electrode 111′ is provided between the pixel electrode 121′ and the touch line Tx′ closest to the pixel electrode 121′ in the first direction X, and the three may form a third electric field at an edge of the sub-pixel Px as shown in FIG. 11. In the embodiments of the present disclosure, a part of the common electrode 111 between the pixel electrode 121 and the touch line Tx is removed to form the third slit SC, and the left side edge of the pixel electrode 121 and the touch line Tx on the left side of the pixel electrode 121 are both exposed by the third slit SC. As no common electrode 111 is provided between the exposed pixel electrode 121 and the exposed touch line Tx, and the touch line Tx is loaded with the same electrical signal as the common electrode 111, the exposed pixel electrode 121 and the exposed touch line Tx may form a fourth electric field as shown in FIG. 12. It is evident from the figures that in the first direction X, a range of the fourth electric field is greater than a range of the third electric field. As such, the light transmitting region TE of the light adjustment portion may be extended in the first direction X. FIG. 13 schematically shows a comparison diagram between a light emitting area of a sub-pixel in a comparative example and a light emitting area of a sub-pixel in an embodiment of the present disclosure, in which TEB represents the light emitting area of the sub-pixel in the comparative example, and TEA represents an expanded light emitting area of the sub-pixel in embodiments of the present disclosure with respect to the light emitting area of the sub-pixel in the comparative example. Referring to FIG. 13, according to the embodiments of the present disclosure, the light transmitting region TE may be extended towards the left side, so that the size of the light transmitting region TE in the first direction X may be increased, and thus the light emitting area of the sub-pixel Px may be increased.

In some specific embodiments, in at least one sub-pixel Px, in the first direction X, the orthographic projection of the third slit SC on the base substrate 100 is located on a side of the orthographic projection of the first slit SA on the base substrate 100 away from the orthographic projection of the second slit SB on the base substrate 100. For example, as shown in FIG. 4, for a sub-pixel Px, the second slit SB is located on the right side of the first slit SA, and the third slit SC is located on the left side of the first slit SA.

In some specific embodiments, in at least one sub-pixel Px, in the second direction Y, the orthographic projection of the second end portion S2 of the third slit SC on the base substrate 100 protrudes from the orthographic projection of the second end portion S2 of the second slit SB on the base substrate 100, so that the touch line Tx may be exposed as much as possible, which is beneficial to the increase of the light emitting area of the sub-pixel Px.

In embodiments of the present disclosure, in at least one sub-pixel Px, in the second direction Y, the orthographic projection of the second portion S22 of the second end portion S2 of the third slit SC on the base substrate 100 at least partially protrudes from the orthographic projection of the second end portion S2 of the second slit SB on the base substrate 100, so that the first portion S21 of the second end portion S2 of the third slit SC is as close as possible to the lower row of sub-pixels Px.

Referring to FIG. 4, in some specific embodiments, at least one touch line Tx includes a touch line body Tx1 and a transfer portion Tx2 that are arranged in the second direction Y. A part connecting the touch line body Tx1 and the transfer portion Tx2 is provided with a bending structure Tx3. The orthographic projection of the second end portion S2 of at least one third slit SC on the base substrate 100 at least partially overlaps with an orthographic projection of the bending structure Tx3 on the base substrate 100.

In the embodiments of the present disclosure, the display substrate may further includes a touch electrode layer provided on the base substrate 100, and the touch electrode layer may include a plurality of touch blocks (not shown). The touch lines Tx and the data lines DL are provided in the first conductive layer, and the touch electrode layer may be on a side of the first conductive layer away from the base substrate 100. The touch line body Tx1 may be electrically connected to a touch block in the touch electrode layer through the transfer portion Tx2, thereby transmitting a touch signal generated on the touch block.

The touch line body Tx1 may include two portions respectively extending in the third direction and the fourth direction, and the bending structure Tx3 may be between the portion extending in the fourth direction and the transfer portion Tx2.

In some specific embodiments, in at least one sub-pixel Px, in the second direction Y, the orthographic projection of the second end portion S2 of the first slit SA on the base substrate 100 protrudes from the orthographic projection of the second end portion S2 of the third slit SC on the base substrate 100. In this way, the size of the third slit SC in the second direction Y may be as large as possible, but does not affect an arrangement of the transfer portion Tx2.

In some specific embodiments, in at least one sub-pixel Px, the orthographic projection of the first portion S21 of the second end portion of the third slit SC at least partially overlaps with the orthographic projection of the thin film transistor 131 used to drive the sub-pixel Px on the base substrate 100 in the first direction X.

For example, in at least one sub-pixel Px, a fourth pattern is defined by the orthographic projection of the first portion S21 of the second end portion of the third slit SC on the base substrate 100, the second pattern is defined by the orthographic projection of the thin film transistor 131 used to drive the sub-pixel Px on the base substrate 100, and the third pattern is defined by the orthographic projection of the gate line GL electrically connected to the sub-pixel Px on the base substrate 100. The second pattern includes the first edge and the second edge that are arranged opposite to each other in the second direction Y. The second edge at least partially overlaps with the third pattern. A distance between the first edge and the third pattern is greater than a distance between the fourth pattern and the third pattern.

In the embodiments of the present disclosure, the fourth pattern defined by the orthographic projection of the first portion S21 of the third slit SC on the base substrate 100 may refer to a pattern defined with an outermost edge of the orthographic projection of the first portion S21 of the third slit SC on the base substrate 100 as a boundary.

In embodiments of the present disclosure, the distance between the first edge and the fourth pattern may refer to a minimum distance between the first edge and the fourth pattern, and the distance between the first pattern and the fourth pattern may refer to a minimum distance between the first edge and the fourth pattern.

In some specific embodiments, the display substrate further includes a plurality of shielding electrodes 112 in the common electrode layer 110, and an orthographic projection of at least one shielding electrode 112 on the base substrate 100 covers an orthographic projection of at least one data line DL on the base substrate 100. By providing the shielding electrode 112, it is possible to avoid interference to the electrical signal on the data line DL.

In embodiments of the present disclosure, in the second direction Y, a distance between a left edge of the shielding electrode 112 and a left edge of the data line DL may range from 2 μm to 4 μm, and a distance between a right edge of the shielding electrode 112 and a right edge of the data line DL may range from 2 μm to 4 μm. For example, both the distances may be 3 μm. The distance between the left edge of the shielding electrode 112 and the left edge of the data line DL may refer to an average distance between the two.

According to the display substrate in the embodiments of the present disclosure, it is possible to increase the light emitting area and thus improve the light emitting efficiency. Specifically, the display substrate in the embodiments of the present disclosure may increase the light emitting efficiency by at least 3% to 5% when compared to conventional display substrates.

In some specific embodiments, at least one sub-pixel Px includes the light transmitting region and the dark region at least partially surrounding the light transmitting region, and a transmittance of the dark region is less than a transmittance of the light transmitting region. In at least one sub-pixel Px, the orthographic projection of the first dark region electrode portion 1111a of the common electrode 111 on the base substrate 100 is located within the range of the orthographic projection of the dark region on the base substrate 100, and the orthographic projection of the light transmitting region electrode portion 1112 on the base substrate 100 is located within the range of the orthographic projection of the light transmitting region on the base substrate 100.

In some specific embodiments, a size of the dark region electrode portion 1111 in the second direction Y ranges from 2 μm to 3 μm. Optionally, at least one of the first dark region electrode portion 1111a and the second dark region electrode portion 1111b has a size in the range of 2 μm to 3 μm in the second direction Y. For example, the size of the first dark region electrode portion 1111a in the second direction Y may be set to 2.5 μm.

In the embodiments of the present disclosure, the light transmitting region TE, the dark region DE, the first dark region electrode portion 1111a and the second dark region electrode portion 1111b have been described in detail above, and details will not be repeated here.

At least some embodiments of the present disclosure further provide a display panel, which includes the display substrate as described above. The display panel has a display area, a peripheral area, and related structures therein. For example, the display panel may be a liquid crystal display panel.

It will be understood that the display panel according to embodiments of the present disclosure has all the features and advantages of the above-mentioned display substrate. Details may be referred to the above descriptions and will not be repeated here.

As least some embodiments of the present disclosure further provide a display device. The display device may include any device or product having a display function. For example, the display device may be a smart phone, a mobile phone, an e-book reader, a desktop personal computer (PC), a laptop PC, a netbook PC, a personal digital assistant (PDA), a portable multimedia player (PMP), a digital audio player, a mobile medical apparatus, a camera, a wearable apparatus (such as a head-mounted apparatus, electronic clothing, electronic bracelet, electronic necklace, electronic accessory, electronic tattoo, or smart watch), a television, etc.

It will be understood that the display device according to the embodiments of the present disclosure has all the features and advantages of the above-mentioned display substrate. Details may be referred to the above descriptions and will not be repeated here.

Although some embodiments of general technical concepts of the present disclosure have been illustrated and described, it will be understood by those ordinary skilled in the art that these embodiments may be changed without departing from the principle and spirit of the general technical concepts of the present disclosure. The scope of the present disclosure is defined by the claims and their equivalents.

1. A display substrate, comprising:
a base substrate;
a plurality of pixel units provided on the base substrate, wherein the plurality of pixel units are arranged in an array in a first direction and a second direction; and
a plurality of data lines provided on the base substrate, wherein the plurality of data lines are arranged in the first direction,
wherein:
at least one of the plurality of pixel units comprises a plurality of sub-pixels, and at least one sub-pixel of the plurality of sub-pixels comprises a common electrode;
in the at least one sub-pixel, the common electrode comprises a dark region electrode portion and a light transmitting region electrode portion arranged in the second direction;
the common electrode are provided with a plurality of slits, at least one of the plurality of slits comprises at least one end portion, the at least one end portion has a first portion, a second portion and a third portion arranged in the second direction, the second portion is located between the first portion and the third portion, the first portion is arranged side by side with an adjacent dark region electrode portion in the first direction, the second portion is arranged side by side with a first part of an adjacent light transmitting region electrode portion in the first direction, and the third portion is arranged side by side with a second part of the adjacent light transmitting region electrode portion in the first direction; and
an orthographic projection of the at least one end portion of the at least one slit on the base substrate is inclined with respect to the second direction, and an inclination of the second portion of the end portion is greater than an inclination of the third portion of the end portion and less than an inclination of the first portion of the end portion.

2. The display substrate according to claim 1, wherein the at least one sub-pixel further comprises a thin film transistor configured to drive the at least one sub-pixel, and in the at least one sub-pixel, the dark region electrode portion of the common electrode comprises a first dark region electrode portion, and the at least one end portion of the at least one slit comprises a first end portion;
wherein an orthographic projection of the first dark region electrode portion on the base substrate is on a side of an orthographic projection of the light transmitting region electrode portion on the base substrate away from an orthographic projection of the thin film transistor on the base substrate; and
wherein the first end portion and an adjacent first dark region electrode portion are arranged side by side in the first direction.

3. The display substrate according to claim 2, wherein in the at least one sub-pixel, the dark region electrode portion of the common electrode further comprises a second dark region electrode portion, and in the second direction, an orthographic projection of the second dark region electrode portion on the base substrate is on a side of the orthographic projection of the light transmitting region electrode portion on the base substrate close to the orthographic projection of the thin film transistor on the base substrate; and
wherein the at least one end portion of the at least one slit further comprises a second end portion, and the first portion of the second end portion is arranged side by side with an adjacent second dark region electrode portion in the first direction.

4. The display substrate according to claim 1, wherein the at least one sub-pixel further comprises a thin film transistor configured to drive the at least one sub-pixel, and in the at least one sub-pixel, the dark region electrode portion of the common electrode comprises a second dark region electrode portion, and the at least one end portion of the at least one slit comprises a second end portion;
wherein an orthographic projection of the second dark region electrode portion on the base substrate is on a side of an orthographic projection of the light transmitting region electrode portion on the base substrate close to an orthographic projection of the thin film transistor on the base substrate; and
wherein the second end portion and an adjacent second dark region electrode portion are arranged side by side in the first direction.

5. The display substrate according to claim 2, wherein in the at least one sub-pixel, the plurality of slits on the common electrode comprise second end portions close to the thin film transistor, and the plurality of slits comprise a first slit and a second slit; and
wherein in the second direction, an orthographic projection of the second end portion of the first slit on the base substrate protrudes from an orthographic projection of the second end portion of the second slit on the base substrate.

6. The display substrate according to claim 5, wherein in the at least one sub-pixel, an orthographic projection of the second portion of the second end portion of the first slit on the base substrate at least partially protrudes from an orthographic projection of the first portion of the second end portion of the second slit on the base substrate in the second direction.

7. The display substrate according to claim 5, wherein in the at least one sub-pixel, an orthographic projection of the second portion of the second end portion of the first slit on the base substrate at least partially overlaps with the orthographic projection of the thin film transistor on the base substrate in the first direction.

8. The display substrate according to claim 1, wherein the at least one slit comprises a first end portion and a second end portion, and an extension direction of the third portion of the first end portion intersects with or is parallel to an extension direction of the third portion of the second end portion.

9. The display substrate according to claim 1, wherein in the at least one end portion of the at least one slit, an orthographic projection of the first portion on the base substrate is inclined with respect to the second direction at a first inclined angle, an orthographic projection of the second portion on the base substrate is inclined with respect to the second direction at a second inclined angle, wherein the first inclined angle and the second inclined angle are acute angles, and a ratio of the second inclined angle to the first inclined angle ranges from 0.1:1 to 0.3:1.

10. The display substrate according to claim 9, wherein in the at least one end portion of the at least one slit, an orthographic projection of the third portion on the base substrate is inclined with respect to the second direction at a third inclined angle, the third inclined angle is an acute angle, and a ratio of the third inclined angle to the second inclined angle ranges from 0.5:1 to 0.9:1.

11. The display substrate according to claim 1, wherein in the at least one end portion of the at least one slit, a ratio of a size of the second portion in the second direction to a size of the first portion in the second direction ranges from 2.7:1 to 3.3:1.

12. The display substrate according to claim 5, further comprising a plurality of touch lines provided on the base substrate, wherein the at least one sub-pixel further comprises a pixel electrode, and the plurality of touch lines are arranged in the first direction; and
wherein the plurality of slits of the common electrode of the at least one sub-pixel further comprise a third slit, and for the pixel electrode of the at least one sub-pixel and a touch line closest to the pixel electrode in the first direction, an orthographic projection of the pixel electrode on the base substrate and an orthographic projection of the touch line on the base substrate at least partially overlap with an orthographic projection of the third slit in the at least one sub-pixel on the base substrate, and the orthographic projection of the pixel electrode on the base substrate is spaced apart from the orthographic projection of the touch line on the base substrate.

13. The display substrate according to claim 12, wherein in the at least one sub-pixel, in the first direction, the orthographic projection of the third slit on the base substrate is on a side of an orthographic projection of the first slit on the base substrate away from an orthographic projection of the second slit on the base substrate.

14. The display substrate according to claim 12, wherein the display substrate further comprises a plurality of shielding electrodes in a common electrode layer, and an orthographic projection of at least one of the plurality of shielding electrodes on the base substrate covers an orthographic projection of at least one of the plurality of data lines on the base substrate.

15. The display substrate according to claim 12, wherein the plurality of touch lines and the plurality of data lines are arranged in a same layer and made of a same material, and the touch line is loaded with a same electrical signal as the common electrode in a common electrode layer.

16. The display substrate according to claim 12, wherein in the at least one sub-pixel, an orthographic projection of the second end portion of the third slit on the base substrate protrudes from the orthographic projection of the second end portion of the second slit on the base substrate in the second direction.

17. The display substrate according to claim 12, wherein in the at least one sub-pixel, the orthographic projection of the second end portion of the first slit on the base substrate protrudes from an orthographic projection of the second end portion of the third slit on the base substrate in the second direction.

18. The display substrate according to claim 12, wherein in the at least one sub-pixel, a ratio of a slit width of the third slit to a slit width of the first slit ranges from 2:1 to 3:1;
wherein in the at least one sub-pixel, an orthographic projection of the first portion of the second end portion of the third slit at least partially overlaps with the orthographic projection of the thin film transistor on the base substrate in the first direction; and
wherein at least one of the plurality of touch lines comprises a touch line body and a transfer portion arranged in the second direction, a portion connecting the touch line body and the transfer portion is provided with a bending structure, and an orthographic projection of the second end portion of the third slit in the at least one sub-pixel on the base substrate at least partially overlaps with an orthographic projection of the bending structure on the base substrate.

19-20. (canceled)

21. The display substrate according to claim 1, wherein the at least one sub-pixel comprises a light transmitting region and a dark region at least partially surrounding the light transmitting region, and a transmittance of the dark region is less than a transmittance of the light transmitting region; and
wherein in the at least one sub-pixel, an orthographic projection of the dark region electrode portion of the common electrode on the base substrate is located within a range of an orthographic projection of the dark region on the base substrate, and an orthographic projection of the light transmitting region electrode portion on the base substrate is located within a range of an orthographic projection of the light transmitting region on the base substrate.

22. (canceled)

23. A display device, comprising a display substrate, wherein the display substrate comprises:
a base substrate;
a plurality of pixel units provided on the base substrate, wherein the plurality of pixel units are arranged in an array in a first direction and a second direction; and
a plurality of data lines provided on the base substrate, wherein the plurality of data lines are arranged in the first direction,
wherein:
at least one of the plurality of pixel units comprises a plurality of sub-pixels, and at least one sub-pixel of the plurality of sub-pixels comprises a common electrode;
in the at least one sub-pixel, the common electrode comprises a dark region electrode portion and a light transmitting region electrode portion arranged in the second direction;
the common electrode are provided with a plurality of slits, at least one of the plurality of slits comprises at least one end portion, the at least one end portion has a first portion, a second portion and a third portion arranged in the second direction, the second portion is located between the first portion and the third portion, the first portion is arranged side by side with an adjacent dark region electrode portion in the first direction, the second portion is arranged side by side with a first part of an adjacent light transmitting region electrode portion in the first direction, and the third portion is arranged side by side with a second part of the adjacent light transmitting region electrode portion in the first direction; and
an orthographic projection of the at least one end portion of the at least one slit on the base substrate is inclined with respect to the second direction, and an inclination of the second portion of the end portion is greater than an inclination of the third portion of the end portion and less than an inclination of the first portion of the end portion.
